(19) United States
(12) Patent Application Publication
(10) Pub. No.: US 2023/0333485 A1
(43) Pub. Date: Oct. 19, 2023

(54) TARGET STRUCTURE AND ASSOCIATED METHODS AND APPARATUS

(71) Applicant: ASML NETHERLANDS B.V., Veldhoven (NL)

(72) Inventors: Wim Tjibbo TEL, Veldhoven (NL); Hermanus Adrianus DILLEN, Veldhoven (NL); Roy WERKMAN, Eindhoven (NL); David Frans Simon DECKERS, Turnhout (BE)

(73) Assignee: ASML NETHERLANDS B.V., Veldhoven (NL)

(21) Appl. No.: 18/025,183

(22) PCT Filed: Sep. 27, 2021
(86) PCT No.: PCT/EP2021/076480

§ 371 Date: Mar. 7, 2023

(30) Foreign Application Priority Data
Sep. 28, 2020 (EP) 20198596.7
Nov. 5, 2020 (EP) 20205996.0

(51) Int. Cl. G03F 7/20

(52) U.S. Cl. CPC G03F 7/70633; G03F 7/70683

(57) ABSTRACT

A substrate including a target structure formed in at least two layers. The target structure includes a first region having periodically repeating features in each of the layers measureable using optical metrology; and a second region having repetitions of one or more product features in each of the layers, the repetitions being sufficient for stochastic analysis to determine at least one local variation metric. The method also includes determining a correction for control of a lithographic process based on measurement of such a target structure.

### CROSS-REFERENCE TO RELATED APPLICATIONS

This application claims priority of EP application 20198596.7which was filed on 28 Sep. 2020 and EP application 20205996.0which was filed on 05 Nov. 2020 and which are each incorporated herein in their entirety by reference.

### FIELD OF THE INVENTION

The present invention relates to a metrology apparatus and methods usable, for example, to perform metrology in the manufacture of devices by lithographic techniques. The invention further relates to such methods for monitoring a local uniformity metric in a lithographic process.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

In lithographic processes, it is desirable frequently to make measurements of the structures created, e.g., for process control and verification. Various tools for making such measurements are known, including scanning electron microscopes, which are often used to measure critical dimension (CD), and specialized tools to measure overlay, the accuracy of alignment of two layers in a device. Recently, various forms of scatterometers have been developed for use in the lithographic field. These devices direct a beam of radiation onto a target and measure one or more properties of the scattered radiation — e.g., intensity at a single angle of reflection as a function of wavelength; intensity at one or more wavelengths as a function of reflected angle; or polarization as a function of reflected angle — to obtain a diffraction “spectrum” from which a property of interest of the target can be determined.

Examples of known scatterometers include angle-resolved scatterometers of the type described in US2006033921A1 and US2010201963A1. The targets used by such scatterometers are relatively large, e.g., 40 µm by 40 µm, gratings and the measurement beam generates a spot that is smaller than the grating (i.e., the grating is underfilled). Examples of dark field imaging metrology can be found in international patent applications US20100328655A1 and US2011069292A1 which documents are hereby incorporated by reference in their entirety. Further developments of the technique have been described in published patent publications US20110027704A, US20110043791A, US2011102753A1, US20120044470A, US20120123581A, US20130258310A, US20130271740A and WO2013178422A1. These targets can be smaller than the illumination spot and may be surrounded by product structures on a wafer. Multiple gratings can be measured in one image, using a composite grating target. The contents of all these applications are also incorporated herein by reference.

Today’s patterning performance is driven by edge placement errors (EPE). The position of the edge of a feature is determined by the features lateral position (Overlay) and the size of the feature (CD). Part of this is very local and stochastic in nature; e.g., dependent on local overlay (LOVL) and local CD uniformity (LCDU). Also, Line Edge Roughness (LER) and line width roughness (LWR) may result in very local CD variations. All of these may be important contributors to the EPE performance.

Currently measurement of these local contributors to EPE may be done using CD-SEM inspection. However, this is too slow for many applications.

It would be desirable to provide a faster method for monitoring EPE and parameters which contributor thereto.

### SUMMARY OF THE INVENTION

The invention in a first aspect provides a substrate comprising a target structure formed in at least two layers, the target structure comprising: a first region comprising periodically repeating features in each of said layers measureable using optical metrology; and a second region comprising repetitions of one or more product features in each of said layers, said repetitions being sufficient for stochastic analysis to determine at least one local variation metric.

The invention in a second aspect provides a method of determining a correction for control of a lithographic process comprising: obtaining an asymmetry metric value for an asymmetry metric, relating to the first region of said target structure on a substrate of the first aspect; using one or more first relationships, each of which relates a measurement value measured from the first region to a measurement value measured from the second region for a respective one of said one or more product features or one or more groups of product features to derive a first local variation metric, and determining the correction from said first local variation metric.

The invention in a third aspect provides a method of designing a target comprising a first region and a second region, the first region comprising periodically repeating features in each of at least two layers and measureable using optical metrology, the second region comprising repetitions of one or more product features in each of said layers, said repetitions being sufficient for stochastic analysis to determine at least one local variation metric, the method comprising optimizing the target structure such that at least one target criterion is met for the target structure.

The invention in a fourth aspect comprises a method for determining a correction for a semiconductor manufacturing process is described, the method comprising: obtaining a plurality of measurement values associated with a performance parameter for a plurality of product features or groups thereof and distributed across a region on a substrate; obtaining tolerance windows associated with the performance parameter for each of the plurality of features; fitting a respective model to the plurality of measurement values for each of the plurality of features or groups thereof; and determining the correction based on determining a correction model which minimizes a distance of parameter values modeled by the respective fitted models to one or more boundaries of its corresponding tolerance window.

The invention yet further provides a computer program product comprising machine-readable instructions for causing a processor to perform the method of the second or third aspect, and associated metrology apparatus and lithographic system.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus;

FIG. 2 depicts a lithographic cell or cluster in which an inspection apparatus according to the present invention may be used;

FIGS. 3 illustrates schematically an inspection apparatus adapted to perform angle-resolved scatterometry and dark-field imaging inspection methods;

FIG. 4 is a schematic illustration of a target structure according to an embodiment of the invention.

FIG. 5 is a flowchart describing a calibration method according to an embodiment of the invention;

FIG. 6 schematically depicts an exposure field or die comprising a number of targets as illustrated in FIG. 4 and corresponding functional areas;

FIG. 7 is a flowchart describing a control method according to an embodiment of the invention 4;

FIGS. 8(a)-(e) are an illustrative schematics describing a control method based on tolerance windows per feature as determined using methods described herein;

FIG. 9 is an illustrative schematic describing a control method based on tolerance windows and per-feature position offsets as determined using methods described herein;

FIG. 10 illustrates a field to part thereof comprising measured and unmeasured locations; and

FIGS. 11(a)-(f) each comprise a plot of value against position illustrating the advantages of a modeling method according to a method of the invention.

### DETAILED DESCRIPTION OF EXEMPLARY EMBODIMENTS

Before describing embodiments of the invention in detail, it is instructive to present an example environment in which embodiments of the present invention may be implemented.

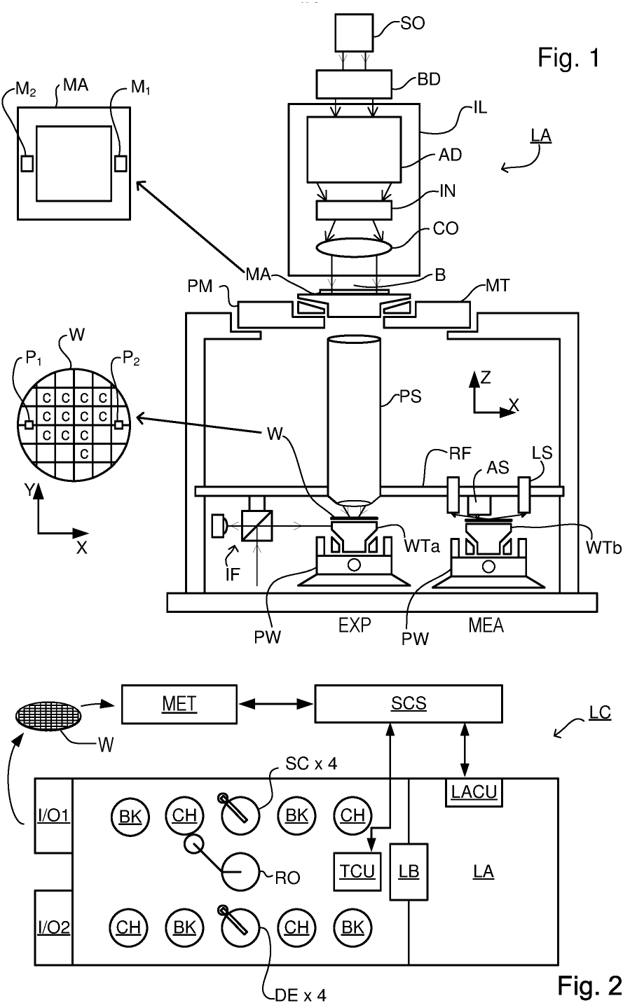

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support holds the patterning device in a manner that depends on the orientation of the patterning device, the design of the lithographic apparatus, and other conditions, such as for example whether or not the patterning device is held in a vacuum environment. The patterning device support can take many forms; the patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., reticle/mask) MA with respect to the path of the radiation beam B, e.g., after mechanical retrieval from a mask library, or during a scan.

Patterning device (e.g., reticle/mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment mark may also be included within dies, in amongst the device features, in which case it is desirable that the markers be as small as possible and not require any different imaging or process conditions than adjacent features. The alignment system, which detects the alignment markers is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations — an exposure station EXP and a measurement station MEA — between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

As shown in FIG. 2, the lithographic apparatus LA forms part of a lithographic cell LC, also sometimes referred to a lithocell or cluster, which also includes apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. Accordingly a manufacturing facility in which lithocell LC is located also includes metrology system MET which receives some or all of the substrates W that have been processed in the lithocell. Metrology results are provided directly or indirectly to the supervisory control system SCS. If errors are detected, adjustments may be made to exposures of subsequent substrates, especially if the inspection can be done soon and fast enough that other substrates of the same batch are still to be exposed. Also, already exposed substrates may be stripped and reworked to improve yield, or discarded, thereby avoiding performing further processing on substrates that are known to be faulty. In a case where only some target portions of a substrate are faulty, further exposures can be performed only on those target portions which are good.

Within metrology system MET, an inspection apparatus is used to determine the properties of the substrates, and in particular, how the properties of different substrates or different layers of the same substrate vary from layer to layer. The inspection apparatus may be integrated into the lithographic apparatus LA or the lithocell LC or may be a stand-alone device. To enable most rapid measurements, it is desirable that the inspection apparatus measure properties in the exposed resist layer immediately after the exposure. However, the latent image in the resist has a very low contrast — there is only a very small difference in refractive index between the parts of the resist which have been exposed to radiation and those which have not — and not all inspection apparatus have sufficient sensitivity to make useful measurements of the latent image. Therefore measurements may be taken after the post-exposure bake step (PEB) which is customarily the first step carried out on exposed substrates and increases the contrast between exposed and unexposed parts of the resist. At this stage, the image in the resist may be referred to as semi-latent. It is also possible to make measurements of the developed resist image — at which point either the exposed or unexposed parts of the resist have been removed — or after a pattern transfer step such as etching. The latter possibility limits the possibilities for rework of faulty substrates but may still provide useful information.

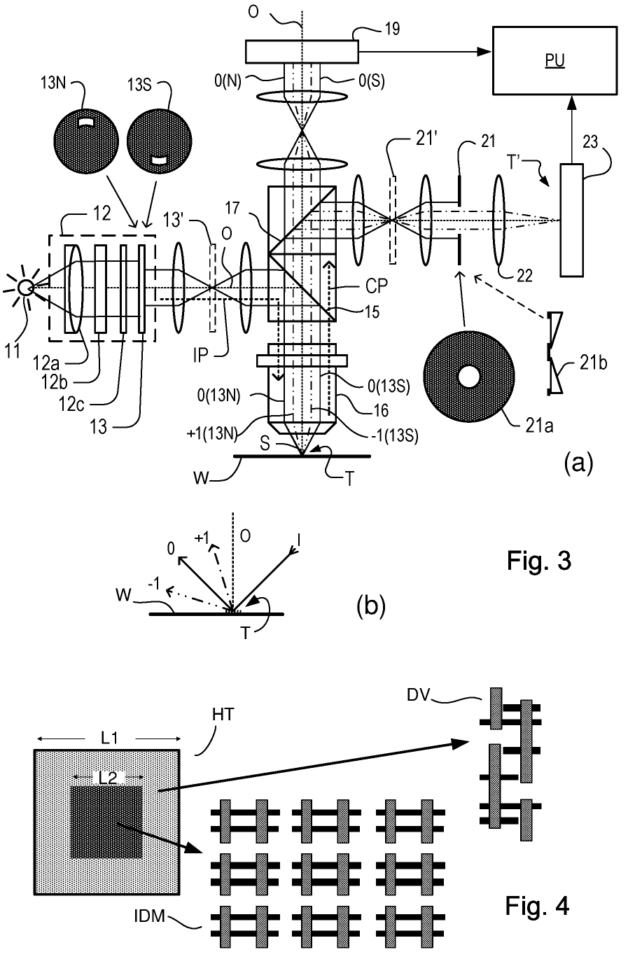

A metrology apparatus suitable for use in embodiments of the invention is shown in FIG. 3(a). Note that this is only one example of a suitable metrology apparatus. An alternative suitable metrology apparatus may use EUV radiation such as, for example, that disclosed in WO2017/186483A1. A target structure T and diffracted rays of measurement radiation used to illuminate the target structure are illustrated in more detail in FIG. 3(b). The metrology apparatus illustrated is of a type known as a dark field metrology apparatus. The metrology apparatus may be a stand-alone device or incorporated in either the lithographic apparatus LA, e.g., at the measurement station, or the lithographic cell LC. An optical axis, which has several branches throughout the apparatus, is represented by a dotted line O. In this apparatus, light emitted by source 11 (e.g., a xenon lamp) is directed onto substrate W via a beam splitter 15 by an optical system comprising lenses 12, 14 and objective lens 16. These lenses are arranged in a double sequence of a 4F arrangement. A different lens arrangement can be used, provided that it still provides a substrate image onto a detector, and simultaneously allows for access of an intermediate pupil-plane for spatial-frequency filtering. Therefore, the angular range at which the radiation is incident on the substrate can be selected by defining a spatial intensity distribution in a plane that presents the spatial spectrum of the substrate plane, here referred to as a (conjugate) pupil plane. In particular, this can be done by inserting an aperture plate 13 of suitable form between lenses 12 and 14, in a plane which is a back-projected image of the objective lens pupil plane. In the example illustrated, aperture plate 13 has different forms, labeled 13N and 13S, allowing different illumination modes to be selected. The illumination system in the present examples forms an off-axis illumination mode. In the first illumination mode, aperture plate 13N provides off-axis from a direction designated, for the sake of description only, as ‘north’. In a second illumination mode, aperture plate 13S is used to provide similar illumination, but from an opposite direction, labeled ‘south’. Other modes of illumination are possible by using different apertures. The rest of the pupil plane is desirably dark as any unnecessary light outside the desired illumination mode will interfere with the desired measurement signals.

As shown in FIG. 3(b), target structure T is placed with substrate W normal to the optical axis O of objective lens 16. The substrate W may be supported by a support (not shown). A ray of measurement radiation I impinging on target structure T from an angle off the axis O gives rise to a zeroth order ray (solid line 0) and two first order rays (dot-chain line +1 and double dot-chain line -1), hereafter referred to as a pair of complementary diffraction orders. It should be noted that the pair of complementary diffraction orders may be any higher order pair; e.g., the +2, -2 pair etc. and is not limited to the first order complementary pair. It should be remembered that with an overfilled small target structure, these rays are just one of many parallel rays covering the area of the substrate including metrology target structure T and other features. Since the aperture in plate 13 has a finite width (necessary to admit a useful quantity of light, the incident rays I will in fact occupy a range of angles, and the diffracted rays 0 and +1/-1 will be spread out somewhat. According to the point spread function of a small target, each order +1 and -1 will be further spread over a range of angles, not a single ideal ray as shown. Note that the grating pitches of the target structures and the illumination angles can be designed or adjusted so that the first order rays entering the objective lens are closely aligned with the central optical axis. The rays illustrated in FIGS. 3(a) and 3(b) are shown somewhat off axis, purely to enable them to be more easily distinguished in the diagram.

At least the 0 and +1 orders diffracted by the target structure T on substrate W are collected by objective lens 16 and directed back through beam splitter 15. Returning to FIG. 3(a), both the first and second illumination modes are illustrated, by designating diametrically opposite apertures labeled as north (N) and south (S). When the incident ray I of measurement radiation is from the north side of the optical axis, that is when the first illumination mode is applied using aperture plate 13N, the +1 diffracted rays, which are labeled +1(N), enter the objective lens 16. In contrast, when the second illumination mode is applied using aperture plate 13S the -1 diffracted rays (labeled 1(S)) are the ones which enter the lens 16.

A second beam splitter 17 divides the diffracted beams into two measurement branches. In a first measurement branch, optical system 18 forms a diffraction spectrum (pupil plane image) of the target structure on first sensor 19 (e.g. a CCD or CMOS sensor) using the zeroth and first order diffractive beams. Each diffraction order hits a different point on the sensor, so that image processing can compare and contrast orders. The pupil plane image captured by sensor 19 can be used for focusing the metrology apparatus and/or normalizing intensity measurements of the first order beam. The pupil plane image can also be used for many measurement purposes such as reconstruction.

In the second measurement branch, optical system 20, 22 forms an image of the target structure T on sensor 23 (e.g. a CCD or CMOS sensor). In the second measurement branch, an aperture stop 21 is provided in a plane that is conjugate to the pupil-plane. Aperture stop 21 functions to block the zeroth order diffracted beam so that the image of the target formed on sensor 23 is formed only from the -1 or +1 first order beam. The images captured by sensors 19 and 23 are output to processor PU which processes the image, the function of which will depend on the particular type of measurements being performed. Note that the term ‘image’ is used here in a broad sense. An image of the grating lines as such will not be formed, if only one of the -1 and +1 orders is present.

Position errors may occur due to an overlay error (often referred to as “overlay”). The overlay is the error in placing a first feature during a first exposure relative to a second feature during a second exposure. The lithographic apparatus minimizes the overlay errors by aligning each substrate accurately to a reference prior to patterning. This is done by measuring positions of alignment marks on the substrate using an alignment sensor. More information on the alignment procedure can be found in U.S. Pat. Application Publication No. US 2010-0214550, which is incorporated herein in its entirety by reference. Pattern dimensioning (e.g., CD) errors may, for example, occur when the substrate is not positioned correctly with respect to a focal plane of the lithographic apparatus. These focal position errors may be associated with un-flatness of a substrate surface. The lithographic apparatus aims to minimize these focal position errors by measuring the substrate surface topography prior to patterning using a level sensor. Substrate height corrections are applied during subsequent patterning to help assure correct imaging (focusing) of the patterning device onto the substrate. More information on the level sensor system can be found in U.S. Pat. Application Publication No. US 2007-0085991, which is incorporated herein in its entirety by reference.

Besides the lithographic apparatus LA and the metrology apparatus MT, one or more other processing apparatuses may be used during device production as well. An etching station (not shown) processes the substrates after exposure of the pattern into the resist. The etch station transfers the pattern from the resist into one or more layers underlying the resist layer. Typically etching is based on application of a plasma medium. One or more local etching characteristics may e.g. be controlled using temperature control of the substrate or directing the plasma medium using a voltage controlled ring. More information on etching control can be found in PCT Patent Application Publication No. WO 2011-081645 and U.S. Pat. Application Publication No. US 2006-016561, which are incorporated herein in their entireties by reference.

During the manufacturing of devices, it is desired that the process conditions for processing substrates using one or more processing apparatuses such as the lithographic apparatus or etching station remain stable such that properties of the features remain within certain control limits. Stability of the process is of particular significance for features of the functional parts of an electric device such as an IC, also referred to as product features. To help ensure stable processing, process control capabilities should be in place. Process control involves monitoring of processing data and implementation of means for process correction, e.g. control a processing apparatus based on one or more characteristics of the processing data. Process control may be based on periodic measurement by the metrology apparatus MT, often referred to as “Advanced Process Control” (further also referenced to as APC). More information on APC can be found in U.S. Pat. Application Publication No. US 2012-008127, which is incorporated herein in its entirety by reference. A typical APC implementation involves periodic measurements on metrology features on the substrates to monitor and correct drifts associated with one or more processing apparatuses. The metrology features reflect the response to process variations of the product features. The sensitivity of the metrology features to process variations may be different compared to the sensitivity to the product features. In that case, a so-called “Metrology To Device” offset (also referenced to as MTD) may be determined.

One reason for this is MTD offset is that the actual product structures are often much (orders of magnitude) smaller than the size of the target structures which are required for scatterometry or imaging measurements, and this difference in size can result in different parameter behavior (e.g., pattern placement and resulting overlay for metrology targets may differ from pattern placement and resulting overlay of actual structures). To mimic the behavior of product features, features within the metrology targets may be made smaller (e.g., of comparable size to the product structures, which can be referred to as at-resolution overlay ARO), incorporate segmented features, assist features or features with a particular geometry and/or dimension. A carefully designed metrology target ideally should respond in a similar fashion to process variations as do the product features. More information on metrology target design can be found in PCT Patent Application Publication No. WO 2015-101458 which is incorporated herein in its entirety by reference.

In another approach, metrology may be performed directly on the product structure. This can be done using a scanning electron microscope (SEM) or an e-beam metrology apparatus for example. However, these devices are typically too slow for process control in a commercial (high-volume manufacturing HVM) environment. Another alternative, referred to as in-device metrology IDM, may comprise using a scatterometer based metrology apparatus to measure the product structure directly. Modern scatterometry tools such as illustrated in FIGS. 3 have the capability of measuring (at least) an asymmetry based metric (e.g., overlay) on such small structures. However, this is only possible for product structures (e.g., types of memory) which have sufficient regularization (are sufficiently periodic) such that they can act as an effective diffraction grating. All features within the spot add to the pupil, so features should be regular over the whole spot in order to get signal. Less regular product structures, such as (for example) logic structures, cannot be measured in this way. Hence basing scanner control purely on such scatterometry derived overlay measurement data may be sub-optimal in view of obtaining highest possible yield (e.g., such that all product structures are printed within their tolerance window or process window in terms of edge placement error (EPE)) particularly for any ICs comprising logic or other non-periodic circuitry.

Consequently, it would be desirable to be able to perform metrology sufficiently fast for HVM control on product structures, and in particular non-periodic product structures such as logic circuits. It would also be desirable for such a method to enable improved monitoring and/or control based on EPE or similar local variation metric.

Local stochastic metrics or local variation metrics, such as local critical dimension uniformity (CDU), local overlay (LOVL), local placement error (LPE), and line width roughness (LWR), overlay margin and/or line edge roughness (LER) are all contributors to the edge placement error (EPE) budget. These effects manifest in dimension variations which are too small to measure using relatively fast metrology tools such as scatterometers, and are therefore presently monitored using SEMs (e.g., e-beam tools) or similar tools.

Disclosed herein is a target (e.g., on a substrate or equivalent features on one or more reticles), and the use of such a target, which enables the establishment of a relationship between an IDM target readout (e.g., a periodic target, more specifically comprising periodic device-like structures, measurable using scatterometry and suitable for scanner control purposes) and a local variation metric (such as product feature local overlay/EPE and/or overlay margin) and/or systematic shifts of non-periodic product features with respect to the scatterometry measurable regular IDM structures.

The established relationship may be used to convert the regularly measured IDM asymmetry metric (e.g., an overlay value) to a corresponding set of second (e.g., corrected) measurement values each corresponding to a different product feature or feature type) and/or a correction for a product local variation metric (e.g., an overlay or EPE correction or related parameter) and use this to subsequently control the scanner.

Such a correction may optimize the local variation metric; e.g., minimize the product EPE. Such methods may be sufficiently fast to enable monitoring and correction of the local variation metric and/or an MTD offset (product to IDM offset) per lot (lot-to-lot) and conceivably also wafer-to-wafer. In particular, methods which enable such measurements to be performed using a scatterometer or interferometer based tool will be described. Such a tool may be a scatterometry based metrology device MET as illustrated in FIG. 2, or the specific metrology device or similar illustrated in FIGS. 3. Alternatively or in addition, such a tool may be an alignment sensor such as that labelled AS in FIG. 1 or any other tool capable of measuring asymmetry in periodic structures.

FIG. 4 illustrates an embodiment of a target structure designed for establishing a relationship between an asymmetry metric measureable using a scatterometer and a local variation metric such as EPE or related metric. The target structure is formed in at least two layers and comprises a first region or periodic (e.g., in-device metrology IDM) target region IDM and second region or device structure region DV, arranged such that they are both simultaneously within a field of view (FOV) of an e-beam metrology tool. As such, the target dimensions may be between 7 µm and 20 µm, between 7 µm and 15 µm, between 8 µm and 12 µm or between 9 µm and 11 µm in each of the substrate plane dimensions. In the specific example shown, the target is square with edge dimension L1 being 10 µm. Dimension L2 may be in the region of 5 µm or smaller for example. More generally, the first region may have dimensions between 3 µm and 7 µm or between 4 µm and 6 µm in each of the substrate plane dimensions.

The proposed target structure may enable, and method comprise, determining relationships for all or some (e.g., more critical) features on die, on a per feature or per group of features (e.g., clip) basis.

The proposed target structure may enable and proposed method comprise determining a first relationship (e.g., an offset or MTD offset) which provides a correction for local overlay or EPE (it may be appreciated that a local overlay MTD offset and an EPE MTD offset will be the same). This may be done per feature / per group of features (or a subset thereof, e.g., critical features/groups of features) such that each of these gets an offset with respect to the IDM region.

The proposed target structure may enable (and optionally proposed method comprise) determining a second relationship (e.g., a contour variability or overlay margin offset) which relates IDM overlay margin from the first region to overlay margin of the features in the second region. This may be done per feature / per group of features (or a subset thereof, e.g., features of interest such as critical features/groups of features) and used to determine a weighting for the respective feature/group in a correction optimization.

The first periodic region may comprise essentially an in-device metrology (IDM) target comprising structures of a similar size or resolution of product structures (e.g., product-like structures) but having a periodic pattern allowing optical measurement of overlay between the two layers of the target. As such, they may resemble as closely as possible the relevant product structures, but have a periodic pattern. This region is typically not actual product structure (although it may be) but specifically designed for scatterometry purposes. The region may comprise, for example, structures similar to memory structures, and as such may comprise structures which are essentially the same as those of one or more product areas on the die (e.g., where the die comprises one or more memory areas). However, the type of structures in this region is ultimately not so important, provided that they are sufficiently periodic to allow for asymmetry based optical metrology (e.g., diffraction based and/or zeroth order asymmetry based) to be performed using a scatterometer or similar device.

The second region may comprise multiple instances of structures which are at least representative of product features on the reticle. These structures may comprise representative examples of periodic and/or non-periodic product structure, or alternatively may comprise actual product structure. In the latter case the target structure may comprise a first periodic region or IDM target placed in the vicinity (e.g., within the same e-beam field of view) as actual device structure. This second region may be the basis for determining stochastic (statistical) behavior of said product features. This behavior may be EPE or a related metric and may describe, for example, a) variation of contours of structures between said two layers or b) variation of a cutline based metric (in case only a limited part of the contour is of interest). The number of instances of these structures within the second region may be of the order of magnitude of thousands or tens of thousands. This second region may comprise multiple clips of product structure, where a clip is a functional entity of multiple features.

As both the IDM target (first) region and product feature (second) region are within one FOV they can be measured simultaneously using an e-beam apparatus or other suitable metrology apparatus having a sufficiently large FOV. Based on the e-beam measurements, the relationship between IDM overlay (layer-to-layer) and one or more local variation metrics (e.g., EPE) of each individual feature, group of features or clip can be established. Any suitable method may be used to determine the local variation metric from the e-beam measurement images.

One such method may comprise determining a first relationship or local overlay relationship (e.g., a local overlay or EPE offset) based on the difference between an overlay value measured from the first region and local overlay measured from the second region; e.g., per feature, per feature of interest (e.g., important or critical features) and/or per group of features (or groups of features of interest). The local overlay values per group or clip may be averaged to provide a local overlay offset per clip with respect to the IDM region which describes the average displacement of the clip features with respect to IDM features. The offset for a particular clip may be applied (e.g., added) in optimization to an IDM measurement (e.g., scatterometer measurement) measured from a region where a particular feature corresponding to that clip is located on the field / wafer.

Another approach may comprise determining a contour variability relationship (a second relationship), such as an overlay margin relationship where overlay margin is the difference between EPE requirement and contour variability (dual layer). The EPE requirement is a consequence of the circuit design, and EPE should be maintained smaller than the EPE requirement. As such EPE comprises the sum of overlay and contour variability dual layer.

An approach for determining overlay margin is contour stacking, which is described in PCT publication WO2020094286A1 (incorporated herein by reference) and may be used to derive the variability of the contours (e.g., it is a contour variability metric, a subset of local variation metrics). The overlay margin relationship may comprise determining a difference between overlay margin for the first region and each of one or more features or groups of features of interest. An alternative method for determining a contour variability metric may comprise gauge analysis (e.g., histogram across cutline).

Overlay margin may be determined from a plurality of images of different layers and parts of a substrate. The method may comprise obtaining one or more images of parts of a substrate on each of a plurality of layers of the substrate. An overlay margin is calculated in dependence on the properties of the features, such as the contours of the features. The images relating to one or more corresponding images of the same feature in different layers of a substrate and/or images of a plurality of features on the same layer of a substrate may be stacked (e.g. aligned and overlaid). The alignment process may be based on aligning the images in dependence on one or more reference positions in, or superimposed onto, each of the images so that there is no overlay error between the images. For example, the alignment process may comprise aligning the target designs of the features in the images so that there is no overlay error between the target designs. The alignment process may be based on aligning the images in dependence on intended design data (e.g., GDS data). The effect of performing the alignment process is to remove the effects of any overlay error between the different images.

The overlay margin is a measure of the stochastic variation of features in the stack of aligned images. The overlay margin may be calculated in dependence on the differences between the contours of corresponding features in the aligned versions of the images. The overlay margin may also be calculated in dependence on the target contours for the features. For example, for each of the images, the overlay margin may be calculated in dependence on a comparison of the feature in the image with the target of the feature. The differences between the contours of features in an image and the contours of features in other images, as well as target contours for the features, can be determined by a plurality of well-known specific image-related metrics, such as critical dimension uniformity (CDU), line width roughness (LWR), critical dimension amplitude and placement errors.

As already stated, overlay margin is related to EPE. EPE is an image-metric that provides an overall representation of the differences between the contours of one or more images of features and a target contours for the features. EPE includes the overlay error between the images of features and the target contours for the features. Overlay margin differs from EPE in that it does not include the overlay error between images of the feature because the overlay error is removed by the above-described alignment process: e.g., Overlay Margin = EPE - Overlay Error.

At a later time, a scatterometry based IDM measurement is made on the first region and from this, a local overlay offset may be applied to each feature or feature group for which a first relationship has been established, this offset providing an EPE correction (e.g., per pixel). In addition, the IDM measurement may be used to predict the corresponding EPE or other local variation metric associated with the product features / clips for which a relationship has been established (e.g., using both of the first relationship and a corresponding overlay margin value) .

The second region of the target structure may comprise many repeats of product features /clips, and may, for example comprise a large number of repetitions of a one or a small number of different clips (i.e., focusing on accurate statistics) or fewer repetition for a larger number of different clips (i.e., focusing on establishing relationships for more relevant product clips in a single calibration). Of course a more balanced strategy between these examples may also be used.

The product features may be arranged around the IDM structures as shown in the drawing so that the closest average proximity between product and IDM structure is maintained. Alternatively, other arrangements are possible (e.g., adjacent regions).

The number of relationship permutations may be too great to establish relationships for every feature type. Therefore, product features may be grouped into clips based on various criteria, which may include, for example, one or more of: a functional criterion (for example grouping according to functional type such that, e.g., all features relating to an SRAM cell are in one clip), criticality (grouping according to process window; e.g., binning according to process window, such that features with similar process windows are in the same clip), geometrical properties (e.g., pitch, CD etc.), or any other criterion for which behavior in exposure and/or metrology of the grouped features can be expected to be similar. Relationships can then be determined per clip or group of features.

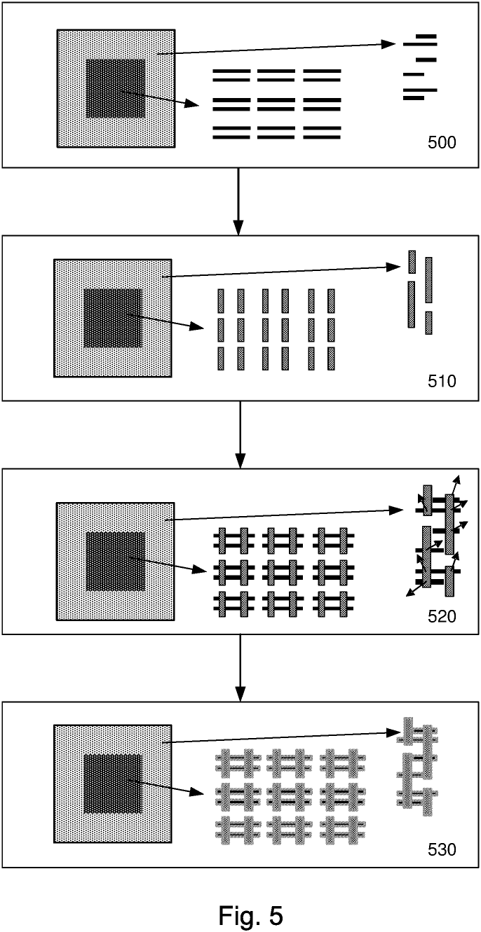

FIG. 5 illustrates a method for determining relationships between asymmetry metric and local variation metric in an initial or calibration stage. At step 500, a first layer is imaged and etched, and then the resultant target arrangement (i.e., first layer component) is measured using an e-beam tool or similar. The step may comprise aligning the e-beam image to an average of the positions of all the IDM features in the first region with respect to respective expected positions; e.g., by referring to a database or GDS file. With the FOV aligned to the first region, a local placement error may be determined by the positions of the product features in the second region with respect to that of the average IDM feature. From this, a placement error per feature can be determined as, for example, an average of the local placement errors per clip or per feature type. Step 510 is essentially the same as step 500 for the second layer, so as to determine placement errors for the second layer. At step 520, a per feature overlay MTD offset (first relationships) with respect to the IDM region is reconstructed from the results of the previous two steps. The overlay for both the first region and all features in the second region can be determined simply from the respective positions of the respective features determined in the steps 500 and 510. The results of this step may be aggregated (e.g., averaged) based on pattern grouping or based on clip (by way of specific example: average local overlay of SRAM cell with respect to IDM) or another method. At step 530, overlay margins are reconstructed for the first region and for the product features. This may be done by contour stacking; e.g., per unit cell (repeating element) of each region. The difference in overlay margin of the first region versus each of the second region clips can be determined from which the second relationships between the IDM measurement and local variation metric can be obtained. This step may also comprise determining the behavior of overlay margin / EPE through focus and/or dose via a focus-exposure matrix (FEM) or other suitable method.

Using the determined relationships, it is possible to determine local corrections for a variation metric such as local overlay or EPE based on measurements performed on IDM targets using a scatterometer. The relationships also enable more efficient monitoring of any variation metric (e.g., overlay margin or EPE) using an e-beam apparatus or similar, e.g., via measurement of only one or more IDM targets, rather than all of the relevant areas separately. Based on these measurements and relationships, for example, control of a process parameter (e.g., overlay control and/or CD control may be optimized). Alternatively or in addition, the measurements and relationships may be used to optimize further metrology, e.g., optimize sampling schemes and metrology strategies.

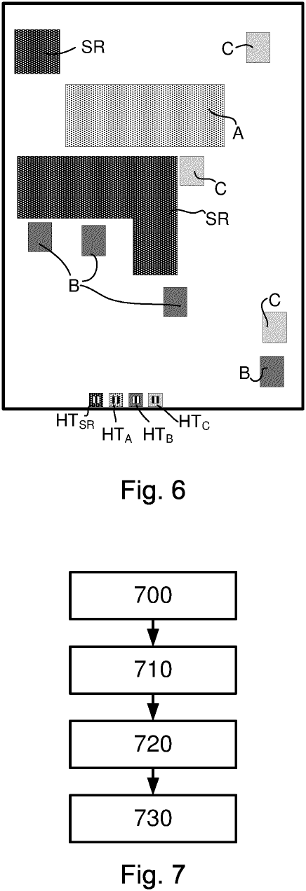

FIG. 6 illustrates a die layout (or part thereof) design for a device which has four different functional areas (e.g., SRAM SR, first logic area A, second logic area B and third logic area C. A functional area may comprise a number of similar features which may be expected to all have a similar relationship with respect to the IDM region and/or are in a common die region; however, this relationship may be different between functional areas. Each functional area has at least one respective hybrid target HT_{SR}, HT_{A}, HT_{B}, HT_{C} which comprises a first periodic or IDM region and a second region with features representative of the features within its respective functional area.

Each of these hybrid targets HT_{SR}, HT_{A}, HT_{B}, HT_{C} may be used to determine a respective first relationship and respective second relationship for each of the four function areas SR, A, B, C using for example the methods described in relation to FIG. 5.

Based on the first relationship determined for each of these functional areas SR, A, B, C, a respective overlay offset may be assigned to each functional area. Based on the second relationship determined for each of these functional areas SR, A, B, C, a respective weight may also be assigned to each functional area; e.g., which depends on the (relative) overlay margin of that feature. These offsets and/or weights may be used during an overlay optimization to control overlay in exposure of the die layout, e.g., such that the respective weight and offset are applied for the pixels on the wafer/field where a corresponding feature occurs.

Overlay margin provides an indication of the tolerance against overlay errors in features that are being manufactured, and as such the weights may be assigned based on the overlay margin assigned (e.g., with lesser importance given to regions for which tolerance is greater). For example, the weights may be assigned based on which functional areas (according to the corresponding overlay margin) have a higher count of EPE critical areas and therefore a higher probability of EPE violation at a given CD/OV error then areas with low amount of EPE critical content.

It may be appreciated that instances/repetitions of many critical features do not occur with sufficient frequency in some logic IC designs for good stochastic analysis; e.g., for determination of a sufficiently accurate overlay margin. A particular advantage of the proposed hybrid target in terms of measuring overlay margin is that the second region may be populated with many instances of one or more critical features (overlay limiting hotspot features) to ensure a sufficient number for good stochastic analysis.

An optimization, by way of specific example, may comprise optimizing overlay for margins either side of a feature (the left and right margins either side of a feature may be asymmetrical), for all features simultaneously. Contour stacking of unit-cells will detect, for each feature within the unit cell, how much it is shifted with respect to EPE best target position (e.g., equal overlay margins left and right) and/or design intent (e.g., stacked contour with respect to GDS file).

The contour stacking step in this embodiment may comprise stacking images of a first layer with one or more images of a second layer for which the first layer is overlay critical (first and second is purely for distinction here does not necessarily denote an exposure order). Once stacked, overlay margins are determined (e.g., in any relevant direction such as left/right and/or top/bottom) to determine any asymmetry in margins for the feature on the first layer with respect to the second layer. Design intent of the second layer may be used if no measurements are available for that layer. For each feature type, this will yield the pattern shift with respect to optimal (where optimal may be equal margin in each dimension; e.g., equal left and right margins). In this manner, pattern shifts per feature type with respect to optimal and with respect to the IDM measurement can be obtained using the hybrid target disclosed herein.

In the optimization, it may be assumed that average of the centers of gravity of all features is zero: i.e., overlay control is perfect but unaware of feature-to-feature pattern shifts within unit-cell (this is done in contour stacking by unit-cell alignment). The optimization may then determine a shift for any measurement point (e.g., to be applied to top vs bottom layer), such that the chance of violating the EPE or overlay margins is minimized. The overlay correction for optimized EPE may comprise the shift which minimizes this chance of failure. A shift fingerprint (intra and/or interfield) may be constructed from all the measurement points (using conventional techniques). This shift fingerprint may be applied in addition to any other overlay correction (which is unaware of feature-to-feature shifts because it is determined only from overlay targets). Each area on reticle that comprises e.g., one of critical designs, may be assigned an offset and weight related to that feature set during such an optimization.

FIG. 7 is a flowchart describing a control strategy according to an embodiment which uses the concepts disclosed herein. At step 700, an IDM measurement or scatterometer measurement of an asymmetry metric is measured from an IDM target (first region of a hybrid target as disclosed herein). At step 710, using the first relationships relating IDM to product variability EPE (which may have been determined in an initial calibration using the methods described), overlay offset data for each of various product features/groups or functional areas are derived. At step 720, an overlay optimization is performed for determining an overlay control correction based on the overlay offset data. This step may also use weights for each feature/group/functional area based on overlay margin (e.g., as determined from the second relationships in the initial calibration stage). At step 740, exposure of the next lot of wafers may be controlled based on the overlay control correction of the previous step, and the method may be repeated on this lot.

The method of FIG. 7 (and methods disclosed herein more generally) may further comprise monitoring for overlay margin using, for example an e-beam or SEM metrology device. This may be done, for example, on the timescale of once a day or every two or three days to verify process is stable. This measurement may be performed, for example, only in the first IDM region as there is more repetition in the IDM region for stochastic monitoring. Provided this overlay margin is stable, it may be assumed that the overlay margin on the other features (and therefore the second relationships/weights) are also stable. Also, based on this assumption that overlay margin is relatively stable between measurements, EPE monitoring may be achieved by summing the (more regular) scatterometer overlay measurement with the (less regular) overlay margin measurements.

While it is presently the case that e-beam measurements are two slow for HVM full edge placement control, it is conceivable that e-beam measurements (or another metrology technology able to monitor overlay margin) will become sufficiently fast such that overlay margin can be measured on, for example, a per lot (or every 2-3 lots) basis. Such a method may measure only the first region in the control setting, and use the first and second relationships to determine the overlay offset and overlay margin per feature/group/functional area . Should this be the case, the concepts disclosed herein also include such edge placement control, such that an edge placement optimization is performed (e.g., per lot) based on the e-beam metrology or combination of e-beam metrology and scatterometer metrology.

As has already been stated, the hybrid target may comprise a first region (periodic IDN region located within the same field of view as actual product structures, such that the second region comprises the actual product structures. As such, a further embodiment may comprise optimizing placement of a periodic target region (e.g., an IDM target) with respect to product structures on a die such that, within a field of view of a metrology device such as an e-beam device (e.g., a region at between 7 µm and 20 µm, between 7 µm and 15 µm, between 8 µm and 12 µm or between 9 µm and 11 µm in each of the substrate plane dimensions), at least one particular target criterion is met. The criterion may comprise, for example, maximizing the occurrence of one or more particular features within the FOV, maximizing the number of different critical features subject to there being sufficient number of each one for stochastic analysis (e.g., based on a threshold), or meeting a predetermined balancing of the number of different critical features and repetitions thereof.

An improved modeling method will now be described which can use the determined relationships (e.g., the determined first relationships or offsets and/or the second relationships) to determine an improved correction for control of the lithographic process. The method comprises using the offsets per feature type (or group of features/functional area) in an optimization step in order to allow optimization per feature. The methods also use the determined overlay margin per feature and methods for determining overlay margins as described above. Furthermore the optimization per feature type may be fitted to and therefore account for measured and non-measured locations. As such, the methods may improve on the methods for constructing shift fingerprints (intra and/or interfield) from all the measurement points as described above.

To optimize for all features (e.g., including those at unmeasured locations) over the wafer it is proposed to infer a model per feature type using the measurements from measured positions and the per feature type relationships. This will lead to a model offset fingerprint per feature type. Subsequently this set of fingerprints (per feature type) may be used to determine an improved correction (e.g., via a Dies In Spec Optimization) using tolerance data or overlay margin data per feature type (e.g., an Overlay Margin Map OMM comprising tolerance windows such as determined using the methods disclosed above). Such an improved correction may take into account margins other than the smallest (most crucial) margin and/or balance all margins rather than only margins corresponding to the measurement locations.

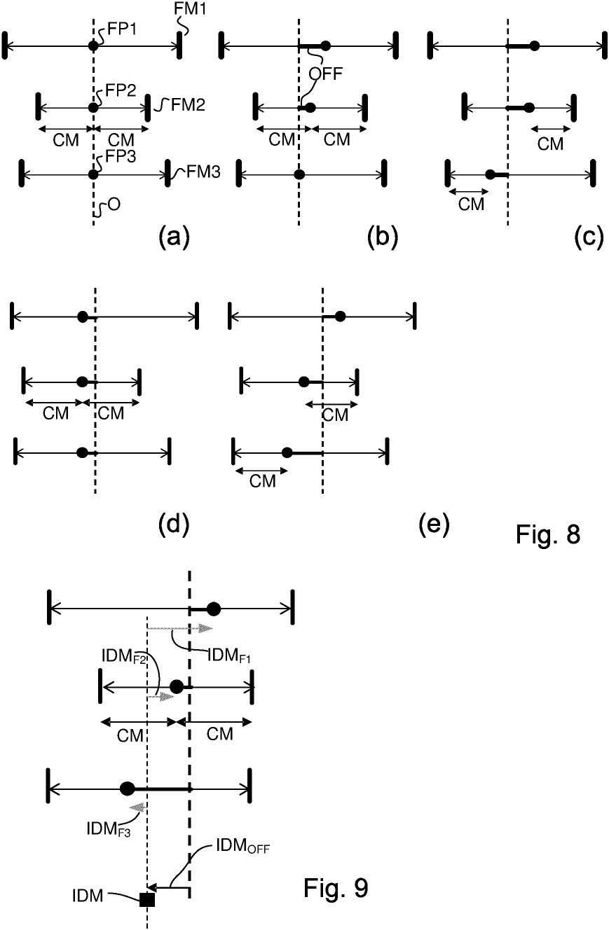

FIGS. 8(a) to (e) illustrate a number of examples as to how, per location, the feature margins may be used to determine optimal placement. Each of these Figures relates to three feature types having respective tolerance windows or feature margins FM1, FM2, FM3 and measured feature positions FP1, FP2, FP3. An origin O describes a position of optimal placement which maximizes critical margins CM or the minimum distance of the position of the most critical feature(s) to a respective limit; i.e., the most critical limit for the whole process in each dimension of the process (in this simple example there is only two dimensions). Note that only FIG. 8(a) is so labeled for brevity. It should be noted that that when the origin O is shifted left or right, then one critical margin becomes larger at the cost of another.

FIG. 8(a) illustrates a perfect (unrealistic) example, where all features are at the same position (origin O) and the feature margins are all symmetrical. The critical margins CM are defined by the smallest feature margin FM2 (this will always be the case in at least one dimension). FIG. 8(b) shows an example where the position of features FP1, FP2, FP3 with respect to origin varies per feature. Once again, the critical margins CM are defined by the smallest feature margin FM2. FIGS. 8(a) and 8(b) result may result in a control strategy which is little different from present methods, where the critical margin is based on the feature with the smallest tolerance window only.

In FIG. 8(c), the position FP3 of the third feature type is closer to its margin bound (on one side) than that of the second feature type. Therefore the critical margin is defined by different feature types (second and third feature types) on each side. By determining a margin bounds or tolerance windows per feature type, therefore, an improved critical margin can be determined based on different feature types.

In each of FIGS. 8(a), 8(b) and 8(c), all of the feature margins are symmetrical around a common point. This is not necessarily the case as illustrated in FIG. 8(d). FIG. 8(d) is a non-symmetrical equivalent to that of FIG. 8(b) while FIG. 8(e) is a non-symmetrical equivalent to that of FIG. 8(c).

FIG. 9 illustrates the effect of an IDM offset IDM_{OFF} being added. In a known method, an MTD offset may be determined based only on a critical feature (i.e., a feature known to have the smallest tolerance window), e.g., by determining the relationship between the critical feature and IDM target. In such a method this single offset IDM_{OFF} is applied when optimizing the placement position (represented by origin O) based on the most critical feature(s) only. Using a hybrid target as described and the determined first relationships (offsets), actual position offsets per feature type IDM_{F1}, IDM_{F2}, IDM_{F3} (gray arrows) are now available. The optimization and control methods described below exploit the availability of these per feature type offsets to model per feature type and determine a correction based on these models.

Also, only data corresponding to measured locations is presently taken into account for the determining of the correction. Basing correction on only measurement data corresponding to selected measurement locations loses valuable information; improved corrections can be obtained by taking into account the actual behavior of the feature across the entire region (e.g., region of interest such as an exposure field).

As such, a method for determining a correction for a semiconductor manufacturing process is described, the method comprising: obtaining a plurality of measurement values associated with a performance parameter for a plurality of product features and distributed across a region on a substrate; obtaining tolerance windows associated with the performance parameter for each of the plurality of features; fitting a respective model to the plurality of measurement values for each of the plurality of features; and determining the correction based on determining a correction model which minimizes a distance of parameter values modeled by the respective fitted models to one or more boundaries of its corresponding tolerance window.

The pattern shift (overlay errors) for multiple features may be determined based on ADI, IDM and/or e-beam based measurements (SEM, HMI). The multiple regression surfaces may be determined to describe the overlay errors (patterns shifts) across the field, each surface dedicated for a particular feature (rather than a fixed coupling of IDM to a single critical feature). Per feature (surface) the overlay margin is also considered, which may comprise the upper and lower bounds of the pattern shift (overlay error) defined per feature across the field. An overlay correction profile may then be determined such that the corrected pattern shift for the ensemble of features gives the highest overlay margin, resulting in a maximum yield (Dies In Spec). The regression surfaces may be determined over all feature locations including those which are not measured.

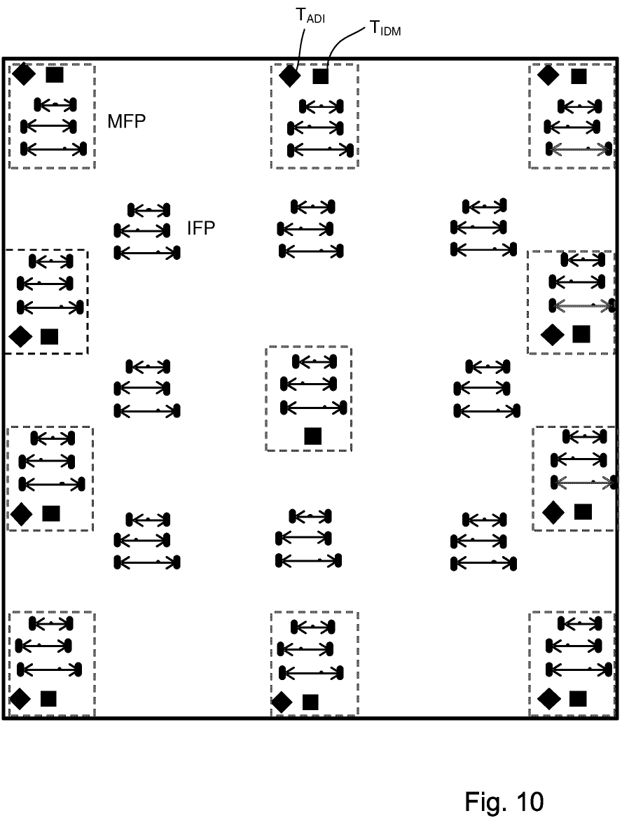

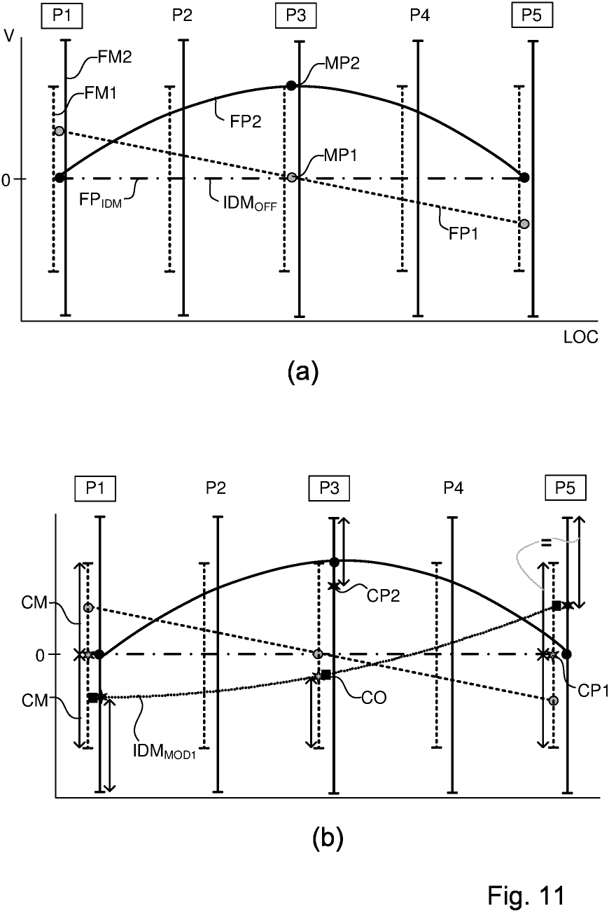

FIG. 10 illustrates that typically only a limited number of measured locations or feature positions MFP are available, e.g., those which comprise a metrology target (e.g., an ADI target T_{ADI} and/or an IDM target T_{IDM}). The unmeasured (inferred) locations or feature positions IFP are not used in modeling or determining corrections in conventional techniques.

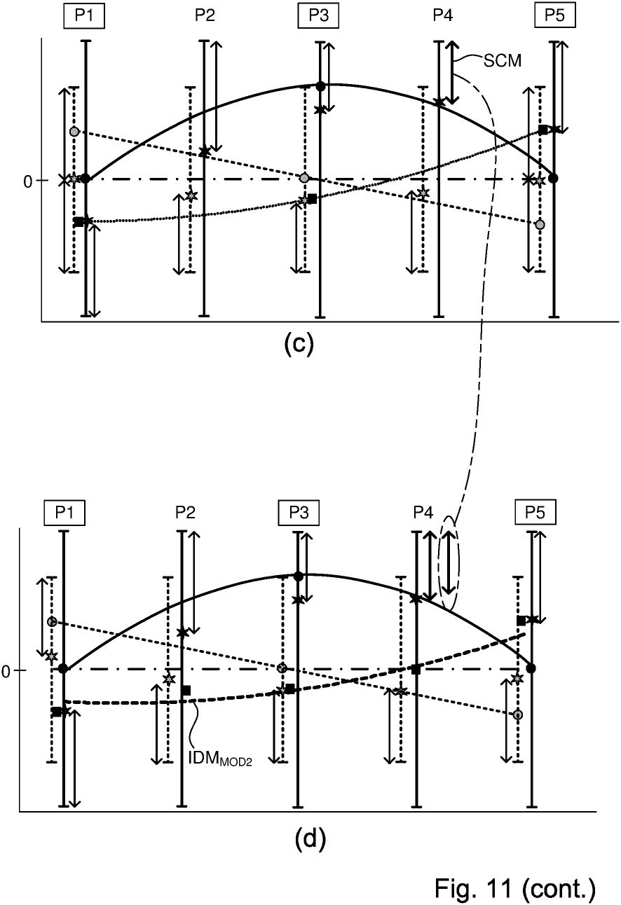

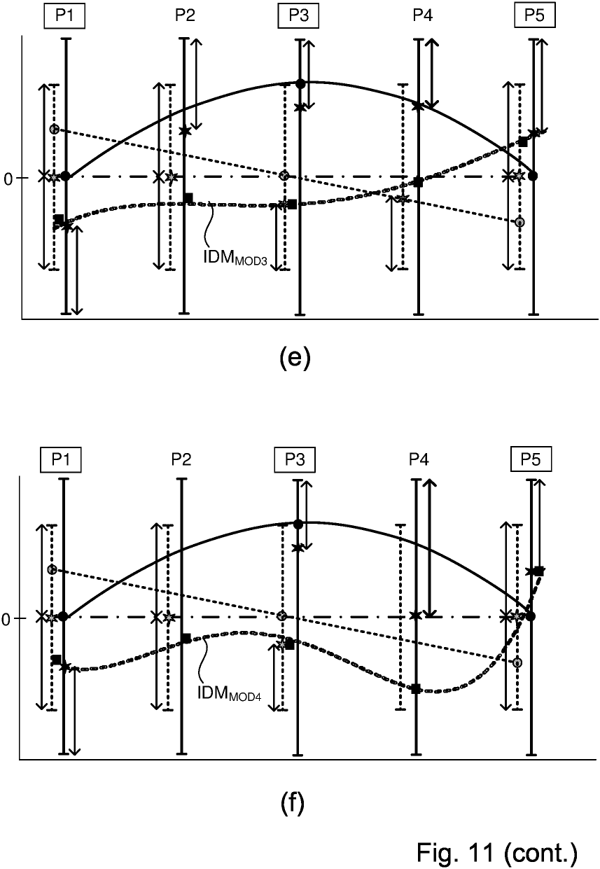

FIGS. 11 illustrates the effect of including inferred values for the unmeasured locations in the regression techniques of this method. Each of FIGS. 11(a) to 11(f) comprises a simplified 1D plot of a (measured or inferred) value for a parameter of interest against location and comprises a simplified description of fingerprints relating to two feature types.

In all of the plots of this Figure, the IDM fingerprint IDM_{FP} is set to V=0 (for each feature type), in order to keep this example simple. Each item on the Figure is labeled only once for brevity and clarity. The plots relate to five locations, positions P1 to P5, where positions P1, P3, P5 are measured and positions P2 and P4 are unmeasured. A first feature type is represented by first measurements MP1 (gray circles) at the measured locations P1, P3, P5 only, a fingerprint FP1 or model (regression) fitted to these first measurements MP1, and feature margins FM1 relating to the first feature. Similarly a second feature type is represented by second measurements MP2 (black circles) at the measured locations P1, P3, P5 only, a fingerprint FP2 or model (regression) fitted to these second measurements MP2, and feature margins FM2 relating to the second feature. In each case, the measured position values MP1, MP2 for each feature is determined from metrology on a common target to determine a common value which is translated to values for each feature based on the offset fingerprints determined using a hybrid target using the methods previously described.

In FIG. 11(b) a correction CO (black square) is determined for each of measured locations P1, P3, P5, based on the smallest margins per measurement location so as to maximize the critical margins CM at each of these measured locations P1, P3, P5. A regression on these corrections yields a correction fingerprint or model IDM_{MOD1}. The corrections result in corrected positions CP1 (gray stars), CP2 (black stars) for the first feature and second feature respectively. This correction fingerprint leads to optimal performance at the measurement locations such that there is no leftover margins (correction potential) at these locations.

However, FIG. 11(c) illustrates that critical margins CM at the non-measured locations P2, P4 are not optimal; instead there is leftover margin at these locations. This is because information regarding the per feature fingerprint is ignored. Here, the corrected positions CP1, CP2 for the unmeasured locations are shown. The smallest critical margin SCM now relates to unmeasured location P4. Using the fingerprint per feature in an optimization step would allow optimization per feature on measured and non-measured locations.

FIG. 11(d) shows that an improved correction IDM_{MOD2} can be determined when the optimization takes into account the non-measured locations P2, P4 such that critical margin CM is also maximized at these locations based on an inferred position from the per-feature fingerprints FP1, FP2. In particular the smallest critical margin CM at location P4 has been improved and there is less leftover correction potential at the locations P2, P4 (possibly balanced against the other locations).

The corrections IDM_{MOD1}, IDM_{MOD2} are both second order corrections. The methods described herein allow a higher order fitting. FIG. 11(e) shows a fourth order fitting to the same data as that of FIG. 11(d), e.g., such that there is no leftover correction potential at any location and all critical margins are optimized. It should be noted that there would be insufficient data to fit a fourth order model in a state of the art methodology, at least in this example.

It is likely that only some features are present at each (e.g., unmeasured) location in the field. The method of this embodiment can account for this, while state of art corrections would be unaffected; i.e., the same correction would be determined in FIG. 11(b) regardless of whether neither, only one or both features were present at locations P2, P4.

FIG. 11(f) comprises a similar plot to that of FIG. 11(e), except that only the first feature is present at location P2 and only the second feature is present at location P4. In prior art methods, the same correction fingerprint IDM_{MOD3} would be determined (assuming a fourth order fitting). However, the methods disclosed herein yield a more optimal (e.g., fourth order although the concept applies to other fitting types) fitting IDM_{MOD4} for this situation.

It is assumed that the given margin maps take into account presence of features on certain image locations such that there where the features are not present, the margins are infinite.

The modeling method of this embodiment will result in increased yield performance, because no information is lost when performing Dies In Spec optimization. A fingerprint difference (e.g., due to Zernike response, or processing) per feature type can be taken optimally into account.

In summary, the hybrid target and methods described above enable local overlay corrections (edge placement error corrections) to be determined by optical metrology (e.g., optical diffraction based metrology and/or optical overlay reconstruction metrology via scatterometer asymmetry measurements, e.g., on a per lot basis. Such optical metrology may encompass asymmetry in opposing higher diffraction orders, and/or asymmetry in the zeroth order (e.g., measured at a pupil plane). Furthermore, any such overlay control may be based on weighted optimization with weights determined from overlay margin measurements of the targets.

Further embodiments may be described in the following clauses:

1. A substrate comprising a target structure formed in at least two layers, the target structure comprising:
a first region comprising periodically repeating features in each of said layers measureable using optical metrology; and
a second region comprising repetitions of one or more product features in each of said layers, said repetitions being sufficient for stochastic analysis to determine at least one local variation metric.

2. A substrate according to clause 1, wherein the periodically repeating features comprise features having a similar size or resolution of said product features.

3. A substrate according to clause 1 or 2, wherein the periodically repeating features are formed in said at least two layers such that intensity and/or phase asymmetry in a zeroth order and/or corresponding diffraction orders varies predictably with overlay.

4. A substrate according to any preceding clauses, wherein the target structure has dimensions between 7 µm and 20 µm in each of the substrate plane dimensions.

5. A substrate according to any preceding clauses, wherein the target structure has dimensions between 8 µm and 12 µm in each of the substrate plane dimensions.

6. A substrate according to any preceding clauses, wherein the first region has dimensions between 3 µm and 7 µm in each of the substrate plane dimensions.

7. A substrate according to any preceding clauses, wherein the first region has dimensions between 4 µm and 6 µm in each of the substrate plane dimensions

8. A substrate according to any preceding clauses, wherein said first region is measurable using diffraction and/or reflection based metrology.

9. A substrate according to any preceding clauses, wherein the first region extends at least across a first area corresponding to a spot size of an optical metrology tool and the combined first region and second region extend at least partially across a second area corresponding to a field of view of an e-beam based metrology tool suitable to measure said one or more product features.

10. A substrate according to any preceding clauses, wherein said repetitions of each of said one or more product features number more than 1000.

11. A substrate according to any preceding clauses, wherein said repetitions of one or more product features comprise representative product features which will not form part of a functioning device, but are representative of product structures forming part of the functioning device.

12. A substrate according to any of clauses1 to 10, wherein said repetitions of one or more product features comprise actual product structures which will form part of a functioning device.

13. A substrate according to any preceding clauses, wherein said product features are grouped into groups, said grouping being based on one or more of: functionality, criticality and geometrical properties.

14. A substrate according to clause 13, wherein said substrate comprises a plurality of said target structures, each comprising a different one or more of said groups in its respective second region.

15. A substrate according to any preceding clauses, further comprising one or more product structures corresponding to said product features.

16. A set of at least two reticles comprising reticle features arranged to image the target structure according to any preceding clauses on said substrate in a plurality of exposures.

17. A method of determining a correction for control of a lithographic process comprising: obtaining an asymmetry metric value for an asymmetry metric, relating to the first region of said target structure on a substrate according to any of clauses1 to 15 or a structure comprising said first region only;
using one or more first relationships to determine a set of second measurement values comprising a second measurement value for each one of one or more product features or one or more groups of product features from said asymmetry metric value; and
determining the correction from the set of second measurement values;
wherein each of said one or more first relationships relates a measurement value measured from the first region to a measurement value measured from a second region of said target structure on a substrate according to any of clauses1 to 15 for a respective one of said one or more product features or one or more groups of product features.

18. A method according to clause 17, wherein the asymmetry metric comprises an intensity and/or phase asymmetry in a zeroth order and/or corresponding diffraction orders of radiation diffracted and/or reflected by said first region or an overlay metric derived therefrom.

19. A method according to clause 17 or 18, wherein each of said one or more groups of product features relates to a different functional area on the die.

20. A method according to any of clauses17 to 19, comprising:
using the one or more first relationships and/or set of second measurement values to derive a first local variation metric; and
determining the correction from said first local variation metric.

21. A method according to clause 20, wherein the first local variation metric comprises local overlay and the correction comprises an overlay offset determined from the local overlay.

22. A method according to clause 21, wherein the overlay offset comprises one or more overlay offsets determined to correct an average of the local overlay for a respective one of one or more groups of said product features.

23. A method according to any of clauses 20 to 22, comprising performing a calibration of said first relationship by:
obtaining an overlay metric calibration value of an overlay metric from the first region;
obtaining first local variation metric calibration values of a first local variation metric for each of said product features from the second region; and
determining said first relationship from a comparison of said first local variation metric calibration values or an average of subsets thereof to said overlay metric calibration value;
wherein said overlay metric calibration value and first local variation metric calibration values relate to a measurement of the target arrangement for which the first region and second region are simultaneously within a field of view of a metrology device used.

24. A method according to any of clauses 17 to 23, wherein the correction is determined as part of a correction optimization.

25. A method according to clause 24, comprising determining one or more second relationships, each of which relates a second local variation metric value measured from the first region to a second local variation metric value measured from the second region for a respective one of said one or more product features or groups of product features.

26. A method according to clause 25, wherein said optimization is based on a weight assigned to each of said one or more groups of product features according to said one or more second relationships.

27. A method according to clause 25 or 26, further comprising measuring said first region periodically to monitor said second local variation metric.

28. A method according to any of clauses 25 to 27, wherein the second local variation metric comprises a contour variability metric.

29. A method according to clause 28, wherein the contour variability metric comprises overlay margin.

30. A method according to clause 28 or 29, comprising performing a calibration of said second relationship by:
obtaining first contour variability metric calibration values of the contour variability metric from the first region;
obtaining second contour variability metric calibration values of the contour variability metric for each of said product features from the second region; and
determining said second relationship from a comparison of said first contour variability metric calibration values and said second contour variability metric calibration values;
wherein said first and second contour variability metric calibration values relate to a measurement of the target arrangement for which the first region and second region are simultaneously within a field of view of a metrology device used.

31. A method according to clause 30, comprising performing contour stacking of corresponding features to obtain the first and second contour variability metric calibration values.

32. A method according to any of clauses 25 to 31, wherein said second relationships are determined for two layers and used to determine a tolerance window for one of said two layers with respect to the other for each of said one or more product features or one or more groups of product features.

33. A method according to any of clauses 24 to 32, wherein said set of second measurement values comprise a plurality of subsets of the second measurement values, each subset relating to a different one of a plurality of product features or groups of product features, and associated with a performance parameter distributed across a region on the substrate; and said method comprises: obtaining tolerance windows associated with the performance parameter for each of the plurality of product features or groups of product features;
fitting a respective model to each subset of the plurality of second measurement values; and
wherein said optimization comprises determining the correction based on determining a correction model which minimizes a distance of parameter values modeled by the respective fitted models to one or more boundaries of its corresponding tolerance window.

34. A method according to clause 33, wherein said region comprises said product features or groups of product features at unmeasured locations; and said step of determining the correction uses inferred values for the performance parameter in the optimization.

35. A method according to clause 34, wherein said optimization comprises performing said maximization of a distance of the modified fitted models to one or more boundaries of its corresponding tolerance window for said unmeasured locations.

36. A method according to any of clauses 17 to 35, comprising performing a metrology operation on said substrate to obtain said asymmetry metric value.

37. A method according to any of clauses 17 to 36, comprising exposing one or more subsequent substrates or lots thereof using said correction.

38. A method of designing a target comprising a first region and a second region, the first region comprising periodically repeating features in each of at least two layers and measureable using optical metrology, the second region comprising repetitions of one or more product features in each of said layers, said repetitions being sufficient for stochastic analysis to determine at least one local variation metric, the method comprising optimizing the target structure such that at least one target criterion is met for the target structure.

39. A method according to clause 38, wherein said optimizing step comprises optimizing placement of the first region with respect to a subset of actual product structures comprised within an exposure field, such that the subset of actual product structures comprises said product features of the second region, and an area comprising said subset of actual product structures defines said second region.

40. A method according to clause 38, wherein said optimizing step comprises optimizing the arrangement of representative product features within the second region.

41. A method according to any of clauses38 to 40, wherein the at least one target criterion comprises one of:
maximizing the occurrence of one or more particular features within the second region,
maximizing the number of different critical features within the second region subject to there being sufficient number of each one for stochastic analysis; or
meeting a predetermined balancing of the number of different critical features within the second region and repetitions thereof.

42. A method according to any of clauses38 to 41, wherein the at least one target criterion comprises one or both of:
optimizing the dimensions of the first area to correspond to a spot size of an optical metrology tool suitable to measure the first area; and
optimizing the dimensions of the combined first region and second region to correspond to a field of view of an e-beam based metrology tool suitable to measure said one or more product features.

43. A method for determining a correction for a semiconductor manufacturing process is described, the method comprising:
obtaining a plurality of measurement values associated with a performance parameter for a plurality of product features or groups thereof and distributed across a region on a substrate;
obtaining tolerance windows associated with the performance parameter for each of the plurality of features; fitting a respective model to the plurality of measurement values for each of the plurality of features or groups thereof; and
determining the correction based on determining a correction model which minimizes a distance of parameter values modeled by the respective fitted models to one or more boundaries of its corresponding tolerance window.

44. A method according to clause 43, wherein said region comprises said product features or groups thereof at unmeasured locations where no measurement is performed; and said step of determining the correction uses inferred values for the performance parameter based on said fitted models.

45. A method according to clause 44, wherein said optimization comprises performing said maximization of a distance of the modified fitted models to one or more boundaries of its corresponding tolerance window for said unmeasured locations.

46. A method according to clause 43, 44 or 44, wherein the plurality of measurement values are obtained from a target measurement of one or more targets and a respective relationship relating each target measurement to one of said product features.

47. A computer program comprising processor readable instructions which, when run on suitable processor controlled apparatus, cause the processor controlled apparatus to perform the method according to any of clauses 17 to 46.

48. A computer program carrier comprising the computer program of clause 47.

49. A processing apparatus comprising:
a processor; and
a computer program carrier comprising the computer program of clause 47.

50. A metrology apparatus comprising the processing apparatus of clause 49.

51. A lithographic exposure apparatus comprising the processing apparatus of clause 49.

The concepts disclosed herein may be design-aware such that the overlay correction takes locally present product features into account. Based on known location of product features (e.g., from a GDS file) within the die area, the desired IDM readout corresponding to a minimal product feature EPE (for example for most critical feature) can be deduced. Subsequently an overlay correction per die area (pixel) may be calculated. Per location it is known what product features are present. After the hybrid target is measured, the relationship between IDM measurement and contour distributions per product may be established. For the relevant location the desired IDM readout can be determined which would correspond to a minimal EPE of the product features present at the location of interest.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The term target should not be construed to mean only dedicated targets formed for the specific purpose of metrology. The term target should be understood to encompass other structures, including product structures, which have properties suitable for metrology applications.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A substrate comprising a target structure formed in at least two layers, the target structure comprising:
a first region comprising periodically repeating features in each of the layers measureable using optical metrology; and
a second region comprising repetitions of one or more product features in each of the layers, the repetitions being sufficient for stochastic analysis to determine at least one local variation metric.

2. The substrate as claimed in claim 1, wherein the periodically repeating features are formed in the at least two layers such that intensity and/or phase asymmetry in a zeroth order and/or corresponding diffraction orders varies predictably with overlay.

3. The substrate as claimed in claim 1, wherein the first region extends at least across a first area corresponding to a spot size of an optical metrology tool and the combined first region and second region extend at least partially across a second area corresponding to a field of view of an e-beam based metrology tool suitable to measure the one or more product features.

4. The substrate as claimed in claim 1, wherein the repetitions of each of the one or more product features number more than 1000.

5. The substrate as claimed in claim 1, wherein the repetitions of one or more product features comprise representative product features which will not form part of a functioning device, but are representative of product structures forming part of the functioning device.

6. The substrate as claimed in claim 1, wherein the one or more product features are grouped into groups, the grouping being based on one or more selected from: functionality, criticality and/or geometrical properties.

7. A set of at least two reticles comprising reticle features arranged to image the target structure as claimed in claim 1 on the substrate in a plurality of exposures.

8. A method of determining a correction for control of a lithographic process, the method comprising:
obtaining an asymmetry metric value for an asymmetry metric, relating to the first region of the target structure on a substrate as claimed in claim 1 or a structure comprising the first region only;
using one or more first relationships to determine a set of second measurement values comprising a second measurement value for each one of one or more product features or one or more groups of product features from the asymmetry metric value; and
determining the correction from the set of second measurement values,
wherein each of the one or more first relationships relates a measurement value measured from the first region to a measurement value measured from a second region of the target structure for a respective one of the one or more product features or one or more groups of product features.

9. The method as claimed in claim 8, comprising:
using the one or more first relationships and/or set of second measurement values to derive a first local variation metric; and
determining the correction from the first local variation metric.

10. The method as claimed in claim 9, wherein the first local variation metric comprises local overlay and the correction comprises an overlay offset determined from the local overlay.

11. The method as claimed in claim 9, further comprising performing a calibration of the first relationship by:
obtaining an overlay metric calibration value of an overlay metric from the first region;
obtaining first local variation metric calibration values of a first local variation metric for each of the product features from the second region; and
determining the first relationship from a comparison of the first local variation metric calibration values or an average of subsets thereof to the overlay metric calibration value,
wherein the overlay metric calibration value and first local variation metric calibration values relate to a measurement of the target arrangement for which the first region and second region are simultaneously within a field of view of a metrology device used.

12. The method as claimed in claim 8, wherein the correction is determined as part of a correction optimization, wherein the set of second measurement values comprise a plurality of subsets of the second measurement values, each subset relating to a different one of a plurality of product features or groups of product features, and associated with a performance parameter distributed across a region on the substrate; and
further comprising:
obtaining tolerance windows associated with the performance parameter
for each of the plurality of product features or groups of product features;
fitting a respective model to each subset of the plurality of second measurement values; and
wherein the optimization comprises determining the correction based on determining a correction model which minimizes a distance of parameter values modeled by the respective fitted models to one or more boundaries of its corresponding tolerance window.

13. A method of designing a target comprising a first region and a second region, the first region comprising periodically repeating features in each of at least two layers and measureable using optical metrology, the second region comprising repetitions of one or more product features in each of the layers, the repetitions being sufficient for stochastic analysis to determine at least one local variation metric, the method comprising optimizing the target structure such that at least one target criterion is met for the target structure.

14. The method as claimed in claim 13, wherein the optimizing comprises optimizing placement of the first region with respect to a subset of actual product structures comprised within an exposure field, such that the subset of actual product structures comprises the product features of the second region, and an area comprising the subset of actual product structures defines the second region.

15. A computer-readable medium storing processor readable instructions which, when run on a suitable processor controlled apparatus, are configured to cause the processor controlled apparatus to perform at least the method of claim 13.

16. The computer-readable medium as claimed in claim 15, wherein the instructions are further configured to cause the processor controlled apparatus to optimize placement of the first region with respect to a subset of actual product structures comprised within an exposure field, such that the subset of actual product structures comprises the product features of the second region, and an area comprising the subset of actual product structures defines the second region.

17. The computer-readable medium as claimed in claim 15, wherein the at least one target criterion comprises one of:
maximization of the occurrence of one or more particular features within the second region,
maximization of the number of different critical features within the second region subject to there being sufficient number of each one for stochastic analysis, or
meeting of a predetermined balancing of the number of different critical features within the second region and repetitions thereof.

18. The method according to claim 13, wherein the optimizing comprises optimizing the arrangement of representative product features within the second region.

19. The method according to claim 13, wherein the at least one target criterion comprises one of:
maximizing the occurrence of one or more particular features within the second region,
maximizing the number of different critical features within the second region subject to there being sufficient number of each one for stochastic analysis, or
meeting a predetermined balancing of the number of different critical features within the second region and repetitions thereof.

20. The method according to claim 13, wherein the at least one target criterion comprises one or both of:
optimizing one or more dimensions of the first area to correspond to a spot size of an optical metrology tool suitable to measure the first area; and/or
optimizing one or more dimensions of the combined first region and second region to correspond to a field of view of an e-beam based metrology tool suitable to measure the one or more product features.
